(19) United States
(12) Patent Application Publication
(10) Pub. No.: US 2010/0075475 A1
(43) Pub. Date: Mar. 25, 2010

(54) METHOD FOR PRODUCING A THIN FILM TRANSISTOR AND METHOD FOR FORMING AN ELECTRODE

(75) Inventors: Satoru TAKASAWA, Sammu-shi (JP); Yuuichi Oishi, Sammu-shi (JP); Miho Shimizu, Sammu-shi (JP); Tooru Kikuchi, Sammu-shi (JP); Satoru Ishibashi, Sammu-shi (JP)

Correspondence Address: KRATZ, QUINTOS & HANSON, LLP, 1420 K Street, N.W., Suite 400, WASHINGTON, DC, 20005, US

(73) Assignee: ULVAC, INC., Chigasaki-shi (JP)

(21) Appl. No.: 12/630,245

(22) Filed: Dec. 3, 2009

Related U.S. Application Data
(63) Continuation of application No. PCT/JP08/60125, filed on Jun. 2, 2008.

(30) Foreign Application Priority Data
Jun. 5, 2007 (JP) 2007-148787

(51) Int. Cl. H01L 21/336; H01L 21/443

(52) U.S. Cl. 438/197; 438/585; 257/E21.478; 257/E21.409

(57) ABSTRACT

An electrode is prevented from being peeled from a substrate or a silicon layer. After the surface of a first copper thin film composed mainly of copper is treated by exposing it to an ammonia gas, a film of silicon nitride is formed on the surface of the first copper thin film by generating a plasma of a raw material gas containing a silane gas and an ammonia gas in an atmosphere in which an object to be processed is placed. Since the surface is preliminarily treated with the ammonia gas, the silane gas is prevented from being diffused into the first copper thin film. Therefore, an electrode constituted by the surface-treated first copper thin film is not peeled from the glass substrate or the silicon layer. In addition, its electric resistance value does not rise.

This application is a continuation of International Application No. PCT/JP2008/060125, filed Jun. 2, 2008, which claims priority to Japan Patent Application No. 2007-148787, filed Jun. 5, 2007. The entire disclosures of the prior applications are herein incorporated by reference in their entireties.

### FIELD OF THE INVENTION

The present invention generally relates to a method for producing thin film transistors. More particularly, the present invention generally relates to a thin film of silicon nitride on a surface of an electrode.

### BACKGROUND OF THE INVENTION

Recently, in order to speed up transistors, there is a demand to replace the current aluminum-based electrodes with electrodes made of a low-resistance metal, and copper is promising as the low-resistance metal.

In a thin film transistor of a liquid crystal display device, for example, a gate electrode is arranged in close contact with a surface of a glass substrate, and a source electrode and a drain electrode are arranged in close contact with a silicon layer. However, there is a problem in that a thin film of pure copper has weak adhesion to the glass substrate and silicon and has a tendency to peel therefrom.

On the other hand, although a thin film of copper containing oxygen has high adhesion to the glass substrate and silicon, it has a high resistance value. Therefore, the merit in employing a copper thin film containing oxygen as the gate electrode is small. Please refer to JP-A 2002-353222.

### SUMMARY OF THE INVENTION

A thin film transistor producing method for producing a thin film transistor is provided. The thin film transistor may include a gate electrode arranged in close contact with a glass substrate, a gate insulating film arranged on a surface of the gate electrode and composed of a thin film of silicon nitride, and a semiconductor layer arranged on the gate insulating film.

The thin film transistor producing method may include the steps of forming a first copper thin film composed mainly of copper and constituting the gate electrode on a surface of the glass substrate by incorporating oxygen into at least a portion of the first copper thin film which adheres to the glass substrate, introducing a treatment gas containing an ammonia gas into a vacuum chamber in which the glass substrate having a surface of the first copper thin film exposed is placed, exposing the surface of the first copper thin film to the ammonia gas for a surface treatment without generating a plasma inside the vacuum chamber, introducing a raw material gas, including a gas of a silicon compound containing Si and H in a chemical structure and a nitrogen containing gas including nitrogen in a chemical structure, into the vacuum chamber, and forming a plasma of the raw material gas, thereby forming the thin film of silicon nitride on the surface of the first copper thin film.

An electrode forming method for forming a copper electrode of copper or a copper alloy on a surface of glass, silicon or a silicon compound exposed on an object to be processed is also provided. The method may include the steps of forming a copper electrode on a substrate by incorporating oxygen into at least a layer in contact with the substrate, performing a surface treatment by exposing a surface of the copper electrode to a treatment gas containing an ammonia gas to obtain a surface-treated substrate, forming a thin film of silicon nitride on the copper electrode by introducing a raw material gas including a gas of a silicon compound containing Si and H in a chemical structure and a nitrogen containing gas including nitrogen in a chemical structure into a film forming atmosphere in which the surface-treated substrate is placed to generate a plasma, and forming a thin film of silicon nitride on the copper electrode to obtain an insulating film.

### BRIEF DESCRIPTION OF THE DRAWINGS

FIGS. 1(a) to (e) are sectional views for illustrating a first half portion of steps to produce a thin film transistor.

FIGS. 2(a) to (d) are sectional views for illustrating a last half portion of the steps to produce the thin film transistor and a step thereafter.

FIG. 3 is a schematic view of a sputtering apparatus.

FIG. 4 is a schematic view of a plasma CVD apparatus.

FIG. 5 is a sectional view for illustrating the structure of a first copper thin film.

FIG. 6 is a sectional view for illustrating a liquid crystal display device.

FIG. 7 is a graph of an Auger analysis.

### DETAILED DESCRIPTION OF THE INVENTION

The invention of this application is hereby described in connection with the detailed descriptions of various embodiments. It is to be understood that the following descriptions of various embodiments are provided for explanatory purposes and not to be construed as to restrict the invention as claimed.

To resolve the above-mentioned problems, a trial has been conducted in which a lower layer portion that is adhered to a glass substrate and a silicon layer was formed with a copper layer containing oxygen, a copper layer containing no oxygen being formed thereon, and a gate electrode, an accumulation capacitor electrode, a source electrode or a drain electrode being constituted by the copper thin film of this two-layer structure.

However, although the copper thin film does not peel from the glass substrate immediately after the copper thin film is formed, the electrode made of the thin copper film peels when a thin film transistor is formed. Therefore, a method of preventing the peeling has been sought.

The inventors of the present invention examined the abrasion states of the electrodes and confirmed the fact that, although the copper thin film did not peel from the glass substrate or the silicon layer in a state immediately after the formation of the copper thin film of the two-layer structure, the electrode peels at an interface of the glass substrate or the silicon layer when a thin film of silicon nitride is subsequently formed on a surface of the electrode formed by patterning the copper thin film.

The thin film of silicon nitride is generally formed by a plasma CVD method in which a raw material for the silicon nitride film comprising a silane gas and a nitrogen containing gas (such as, a nitrogen gas, an ammonia gas or the like) that is added to the silane gas, is introduced into a vacuum chamber, and a plasma of a gas made of the raw material for the silicon nitride film is generated.

A component gas in the gas made of the raw material for the silicon nitride film is decomposed by the plasma, and causes a reaction on a surface of an object to be film-formed, whereby a thin film of silicon nitride is formed. From such steps, it is considered that the component gas in the raw material gas influences the tendency of the electrode to peel.

In view of this, a sample piece in which a copper thin film of a two-layer structure was formed on a glass substrate; the sample piece was placed in a vacuum chamber; a nitrogen gas was introduced into the vacuum chamber; and the sample piece was heated in an atmosphere at a pressure of 120 Pa. Thereafter,

(1) a peeling test was performed as-is,
(2) a peeling test was preformed after the sample piece was exposed to a mixed gas of a nitrogen gas and an ammonia gas (120 Pa, N₂: 500 sccm, NH₃: 300 sccm),
(3) a peeling test was performed after the sample piece was exposed to a mixed gas of a nitrogen gas and a silane gas (120 Pa, N₂: 500 sccm, SiH₄: 20 sccm), or
(4) a peeling test was performed after the sample piece was exposed to a mixed gas of a nitrogen gas, an ammonia gas and a silane gas (120 Pa, N₂: 500 sccm, NH₃: 300 sccm, SiH₄: 20 sccm).

From the results of the above peeling tests, it was revealed that the peeling occurred in the cases of (3) and (4), both of which utilized a mixed gas containing a silane gas.

In order to confirm whether the presence of the silane gas was indeed influencing the tendency of the electrode to peel, a sample piece was formed with a copper thin film (film thickness: 300 nm) composed mainly of copper added with Mg on a surface of a glass substrate, and the sample piece was exposed to a mixed gas of the nitrogen gas and the silane gas for 3 minutes while being heated at 300° C. And then, an Auger analysis was conducted on the copper thin film.

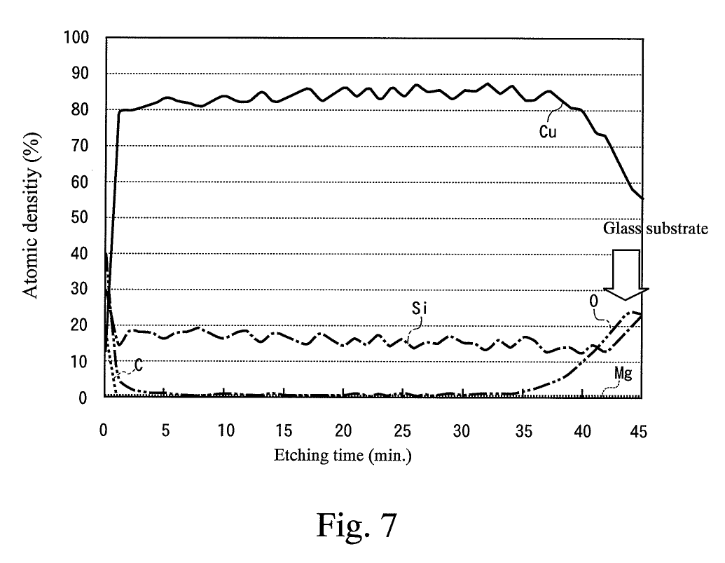

The results obtained thereof are shown in FIG. 7.

In the graph of FIG. 7, the ordinate represents the atomic density, and the abscissa represents the etching time period. As illustrated by the graph of FIG. 7, it is understood that Si derived from the silane gas is distributed from the surface of the copper thin film up to an interface between the glass substrate and the surface of the copper thin film; thus, the silane gas diffuses up to the interface between the glass substrate and the copper thin film.

Also, the sheet resistance of the copper thin film is 0.0958Ω/□ before the exposure to the mixed gas, whereas it rises to 1.121Ω/□ after the exposure to the mixed gas. Thus, it is concluded that the diffusion of the silane gas raises the resistance value of the copper thin film.

The symbol “□” stands for “square” and means resistive element in a square sheet of resistive element. The unit “Ω/□” stands for “Ω/square,” which means sheet resistance of a square sheet and measurement is usually made by the “Van der Pauw method.”

In addition, when CuO exists at a portion where the copper thin film contacts the glass substrate, it is considered that, since this CuO is denatured by the hydrogen of the silane gas, the copper thin film has a tendency to peel from the glass substrate and the silicon layer.

If it is true, the influence of the silane gas need only be prevented from extending to the interface between the copper thin film and the glass substrate and/or the interface between the copper thin film and the silicon layer.

An embodiment of the present invention, which has been accomplished based on the above knowledge, is directed to a thin film transistor producing method for producing a thin film transistor which includes a gate electrode arranged in close contact with a glass substrate, a gate insulating film arranged on a surface of the gate electrode and composed of a thin film of silicon nitride, and a semiconductor layer arranged on the gate insulating film, the thin film transistor producing method comprising the steps of forming a first copper thin film composed mainly of copper and constituting the gate electrode on a surface of the glass substrate by incorporating oxygen into at least that portion of the first copper thin film which adheres to the glass substrate, introducing a treatment gas containing an ammonia gas into a vacuum chamber in a state that the glass substrate having a surface of the first copper thin film exposed is placed in the vacuum chamber, exposing the surface of the first copper thin film to the ammonia gas for a surface treatment without generating a plasma inside the vacuum chamber, introducing a raw material gas, to which a gas of a silicon compound containing Si and H in a chemical structure and a nitrogen containing gas containing nitrogen in a chemical structure are added, into the vacuum chamber, and forming a plasma of the raw material gas, thereby making the thin film of silicon nitride develop on the surface of the first copper thin film.

An embodiment of the present invention is directed to the thin film transistor producing method comprising the step of exposing the surface of the first copper thin film to the ammonia gas for 10 seconds or more for the surface treatment.

An embodiment of the present invention is directed to the thin film transistor producing method comprising the step of setting the partial pressure of a monosilane gas at 1/15 or less of the partial pressure of the ammonia gas inside the vacuum chamber for the surface treatment.

An embodiment of the present invention is directed to the thin film transistor producing method comprising the step of introducing the treatment gas such that the partial pressure of the ammonia gas inside the vacuum chamber may be 60 Pa or more for the surface treatment.

An embodiment of the present invention is directed to a thin film transistor producing method for producing a thin film transistor which includes a gate electrode, a gate insulating film arranged on a surface of the gate electrode, a semiconductor layer arranged on the gate insulating film, a source electrode in contact with the semiconductor layer, a drain electrode in contact with the semiconductor layer, and an insulating film in contact with the drain electrode and the source electrode and composed of a film of silicon nitride, the thin film transistor producing method comprising the steps of forming a second copper thin film constituting the source electrode and the drain electrode on a surface of the semiconductor layer by incorporating oxygen into at least a portion in close contact with the semiconductor layer, introducing a treatment gas containing an ammonia gas into a vacuum chamber in a state that an object to be processed, which has a surface of the second copper thin film exposed, is placed in the vacuum chamber, exposing the surface of the second copper thin film to the ammonia gas without generating a plasma inside the vacuum chamber for the surface treatment, introducing a raw material gas, to which a gas of a silicon compound containing Si and H in a chemical structure a nitrogen containing gas containing nitrogen in a chemical structure are added, into the vacuum chamber, and forming a plasma of the raw material gas, thereby making the thin film of silicon nitride grow on the surface of the second copper thin film.

An embodiment of the present invention is directed to the thin film transistor producing method comprising the step of exposing the surface of the second copper thin film to the ammonia gas for 10 seconds or more for the surface treatment.

An embodiment of the present invention is directed to the thin film transistor producing method comprising the step of setting the partial pressure of a monosilane gas at 1/15 or less of the partial pressure of the ammonia gas inside the vacuum chamber for the surface treatment.

An embodiment of the present invention is directed to the thin film transistor producing method comprising the step of introducing the treatment gas such that the partial pressure of the ammonia gas inside the vacuum chamber may be 60 Pa or more for the surface treatment.

An embodiment of the present invention is directed to the thin film transistor producing method, wherein the semiconductor layer comprises first and second ohmic contact layers, the source electrode is in contact with the first ohmic contact layer, and the drain electrode is in contact with the second ohmic contact layer.

An embodiment of the present invention is directed to an electrode forming method for forming a copper electrode of copper or a copper alloy on a surface of glass, a surface of silicon or a surface of a silicon compound exposed on an object to be processed, comprising a copper electrode forming step for forming the copper electrode on the substrate by incorporating oxygen into at least a layer in contact with the substrate, a surface treatment step for performing a surface treatment by exposing a surface of the copper electrode to a treatment gas containing an ammonia gas, and an insulating film forming step for forming a thin film of silicon nitride on the copper electrode by introducing a raw material gas, to which a gas of a silicon compound containing Si and H in a chemical structure and a nitrogen containing gas containing nitrogen in a chemical structure are added, into a film forming atmosphere in which the surface-treated substrate is placed to generate a plasma, and forming a thin film of silicon nitride on the copper electrode.

An embodiment of the present invention is directed to the electrode forming method comprising the step of setting the partial pressure of the ammonia gas at 60 Pa or more in the treatment atmosphere in which the substrate is placed, in the surface treatment step.

An embodiment of the present invention is directed to the electrode forming method, wherein a time period for exposing the copper electrode to the ammonia gas in the surface treatment step is 10 seconds or more.

An embodiment of the present invention is directed to the electrode forming method, wherein, in the surface treatment step, the partial pressure of the silicon compound gas contained in the treatment atmosphere is set at 1/15 or less of the partial pressure of the ammonia gas.

In the context of this application, the expression “copper as a main component” refers to the inclusion of a copper element, and particularly to a case in which the content of the copper element is 50 percent by mass or more. For example, a material having “copper as a main component” corresponds to pure copper or copper alloys and the like.

According to the thin film transistor producing method according to an embodiment of the present invention, the surface of the electrode is reformed by contacting the non-plasmatized ammonia gas with the electrode so that the influence of the silane gas may not be extended to an interface of the glass substrate or the silicone layer. Therefore, the peeling of the electrode composed mainly of copper is prevented.

Some effects accomplished by various embodiments of the invention are as follows.

The electrode is hardly peeled from the glass substrate or the silicon layer. The sheet resistance of the electrode does not rise. The film of silicon nitride is hardly peeled from the electrode.

Various embodiments of methods according to the present invention are hereby described in view of the drawings as follows.

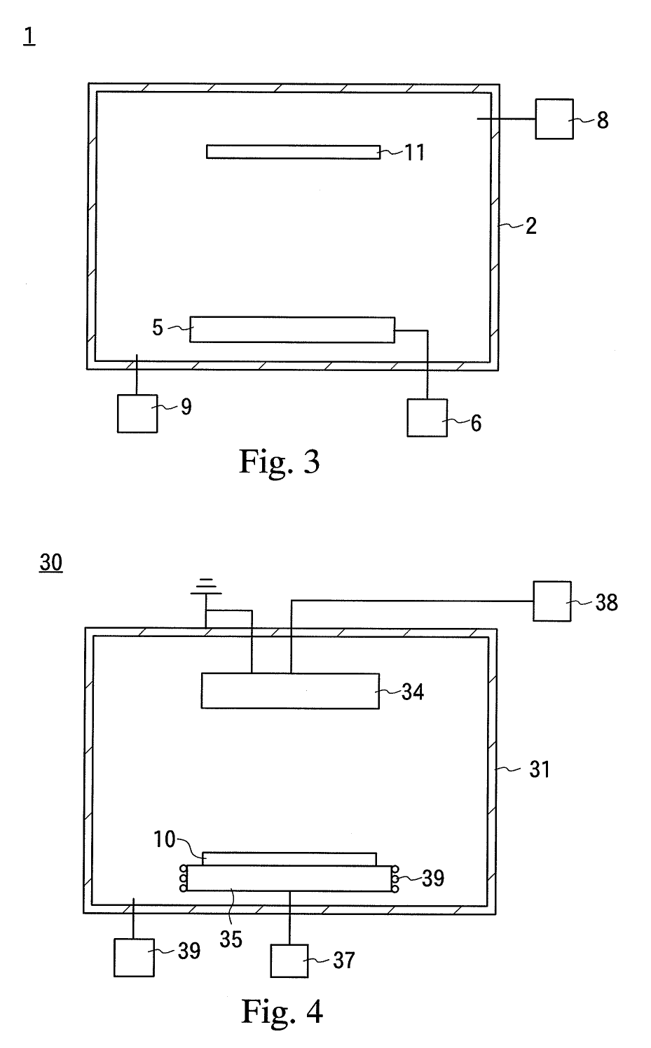

In FIG. 3, a reference numeral 1 denotes a sputtering apparatus, and a target 5 composed mainly of copper is arranged inside a sputtering chamber 2.

A vacuum evacuation system 9 and a gas introduction system 8 are connected to the sputtering chamber 2. While a vacuum atmosphere is formed by evacuating the interior of the sputtering chamber 2 by the vacuum evacuation system 9, a glass substrate as an object to be film-formed is carried into the interior of the sputtering chamber 2. In the same figure, a reference numeral 11 shows the glass substrate which is carried in the interior of the sputtering chamber 2.

The sputtering chamber 2 is connected to a ground potential. A sputtering gas (for example, a noble gas such as argon or the like) and an oxygen gas are introduced from the gas introduction system 8; a voltage is applied to the target 5 composed mainly of copper from the sputtering power source 6; a plasma of the sputtering gas and an oxygen gas is generated; the target 5 composed mainly of copper is sputtered; and a first layer made of a thin film composed mainly copper and containing oxygen is formed on a surface of the glass substrate 11.

Next, the introduction of the oxygen gas is stopped. Further, while the vacuum evacuation and feeding of the sputtering gas are being continued, the target 5 composed mainly of copper is sputtered with the plasma of the sputtering gas. Thus, a second layer composed mainly of copper and containing no oxygen is formed. Consequently, a copper thin film having a two-layer structure is obtained.

The first layer and the second layer may be formed by sputtering the same target 5, or may be formed by sputtering different targets. As the target 5, a target of pure copper as well as a target composed mainly of copper with the addition of at least one kind of added metals, such as Mg, Ni, Zr, Ti and the like, can be used. One or more types of the added metals can be added into either one or both of the first layer and the second layer.

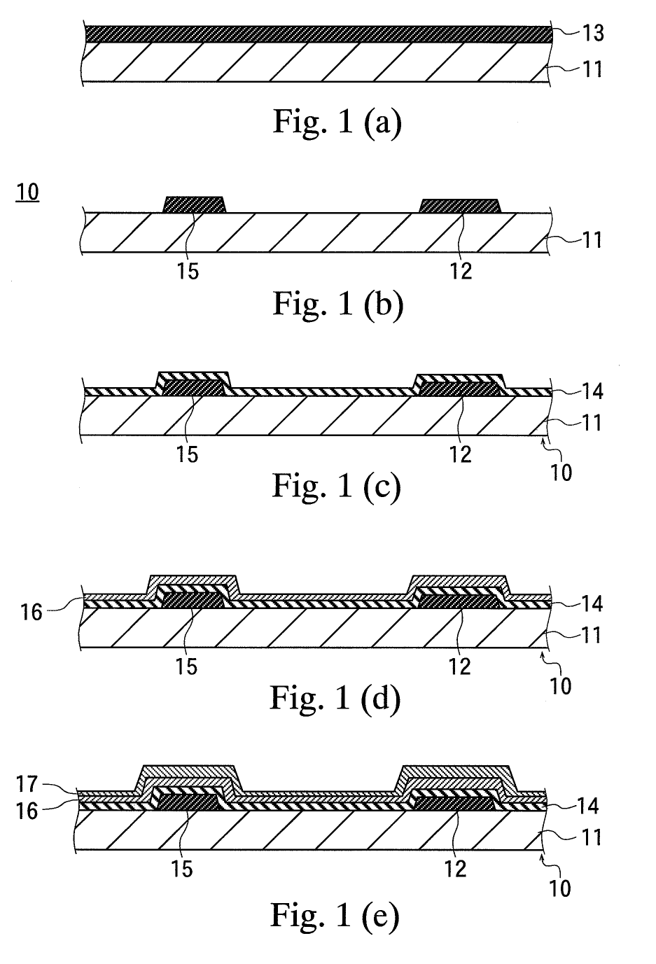

FIG. 1(a) illustrates a state in which a copper thin film (first copper thin film 13) of a two-layer structure composed mainly of copper is formed on a surface of a glass substrate 11.

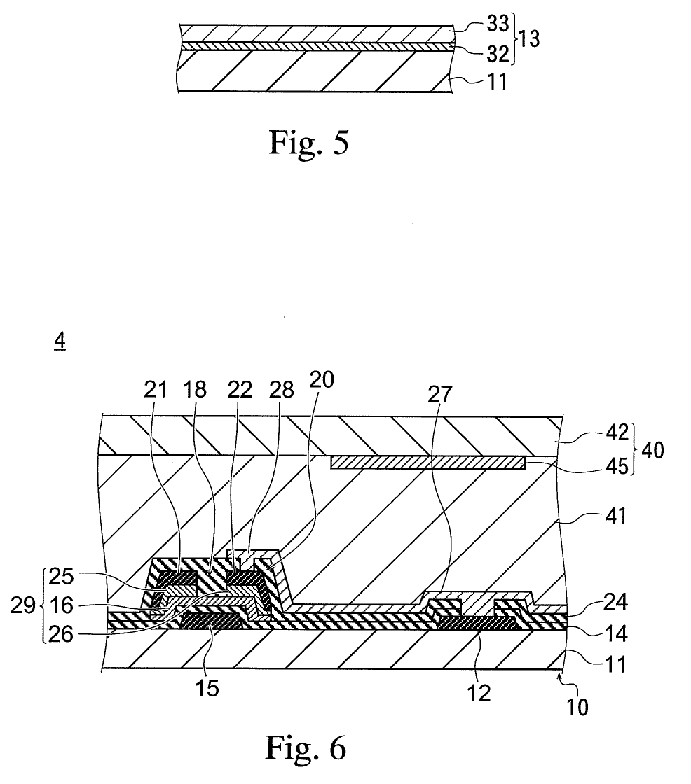

FIG. 5 is an enlarged sectional view of FIG. 1(a). A first layer 32 containing oxygen is adhered to the glass substrate 11. Since the first layer 32 has stronger adhesion to the glass substrate 11 than the second layer 33 containing no oxygen, the first copper thin film 13 is firmly fixed to the glass substrate 11 by means of the first layer 32.

The first copper thin layer 13 comprises not only the first layer 32 but also the second layer 33 containing no oxygen, and the second layer 33 is disposed in contact with a surface of the first layer 32. Since the second layer 33 has a lower electric resistance than the first layer 32, the first copper thin film 13 of the two-layer structure has a lower electric resistance than in a case where the copper thin layer is formed with the first layer 32 alone.

Next, when the first copper thin film 13 is patterned by a photographing step and an etching step, as shown in FIG. 1(b), a gate electrode 15 and a storage capacitor electrode 12 are formed on a surface of the glass substrate 11 by the patterned first copper thin film 13.

In FIG. 1(b), a reference numeral 10 is an object to be processed, in which the gate electrode 15 and the storage capacitor electrode 12 are exposed on the glass substrate 11.

In FIG. 4, a reference numeral 30 denotes a plasma CVD apparatus to be used for processing a surface of the object 10 to be processed and forming a nitride film.

This plasma CVD apparatus 30 includes a CVD chamber 31 (vacuum chamber), and a shower head 34 is arranged at an inside ceiling of the CVD chamber 31.

The shower head 34 is connected to a gas introduction system 38. The gas introduction system 38 comprises a tank in which an ammonia gas is stored, a tank in which a silicon compound gas (a silane gas such as monosilane, disilane or the like) is stored, and a tank in which a nitrogen gas is stored.

A flow rate controller is provided in the gas introduction system 38 so that the ammonia gas, the silane gas and the nitrogen gas can respectively be fed into the shower head 34 by predetermined flow rates.

The shower head 34 is provided with a plurality of ejection openings not shown in the drawing. A mixed gas containing the ammonia gas, the silane gas and the nitrogen gas at predetermined ratios is fed into the CVD chamber 31 through the ejection openings.

A vacuum evacuation system 39 is connected to the CVD chamber 31; the interior of the CVD chamber 31 is evacuated to form a vacuum atmosphere; and then the object 10 to be processed, in which surfaces of the gate electrode 15 and the storage capacitor electrode 12 are exposed, is carried into the interior of the CVD chamber 31.

A mounting table 35 is arranged at a position opposed to the shower head 34 along a bottom wall of the CVD chamber 31.

The mounting table 35 is provided with a heater 39. An electric current is preliminarily passed through the heater 39; the object 10 carried into the interior of the CVD chamber 31 is placed on the mounting table 35; and the object 10 to be processed is heated, while an inert gas is being fed into the CVD chamber 31.

Although the inert gas is not particularly limited, no superfluous gas mixes in the film forming step if a gas to be added into the below-described raw material gas, like the nitrogen gas (N₂), is used.

When the object 10 to be processed reaches a predetermined processing temperature, the introduction of the inert gas is stopped and the inert gas is evacuated while that temperature is maintained.

Either the mounting table 35 or the shower head 34 may be connected to a high frequency power source 37, and the other (the shower head 34 or the mounting table 35) may be connected to the ground potential. In the depicted embodiment, the mounting table 35 is connected to a high frequency power source 37, and the shower head 34 is connected to a ground potential.

The vacuum evacuation is continued in the state that the object 10 to be processed is maintained at the predetermined temperature; the object 10 to be processed is exposed to the non-plasmatized treatment gas by ejecting only the ammonia gas or a treatment gas in which either one or both of the silane gas and the nitrogen gas are added to the ammonia gas, while the high frequency power source 37 is maintained in the off state.

Since the gate electrode 15 and the storage capacitor electrode 12 (and the other portion of the first copper thin film 13) are exposed from the surface of the object 10 to be processed, these electrodes are exposed to and surface-treated with the ammonia gas in the treatment gas.

After object 10 to be processed is exposed to the treatment gas for 10 seconds or more, the ratio of the partial pressure of the silane gas with respect to that of the ammonia gas is increased from the ratio at the time of the surface treatment by increasing the flow rate of the silane gas with respect to that of the ammonia gas, while the CVD chamber 31 is being evacuated.

After the inner pressure of the CVD chamber 31 is stabilized at a predetermined pressure, when the high frequency voltage is applied between the shower head 34 and the mounting table 35 by turning on the high frequency power source 37, a plasma of the raw material gas is formed above the surface of the object 10 to be processed, and as shown in FIG. 1(c), a gate insulating film 14 composed of a thin film of silicon nitride (SiNₓ) grows on the surfaces of the gate electrode 15 and the storage capacitor electrode 12 (and the other portion of the first copper thin film 13) which are surface-treated.

When the gate insulating film 14 is formed, the first copper thin film 13 is exposed to a greater amount of the silane gas as compared to the time of the surface treatment.

However, since the surface of the first copper thin film 13 is treated with the ammonia gas, the influence of the silane gas does not reach the interface between the first copper thin film 13 and the glass substrate 11, so that the electrodes such as the gate electrode 15 and the storage capacitor electrode 12 constituted by the first copper thin film 13 do not peel from the glass substrate 11.

After the gate insulating film 14 of a predetermined thickness is formed, the application of the voltage and the introduction of the raw material gas are stopped, the plasma is diminished, and the raw material gas is evacuated. While the interior of the CVD chamber 31 is being continuously evacuated, the raw material gas for channel is introduced and ejected into the CVD chamber 31 through the ejection openings.

When the CVD chamber 31 is stabilized at a predetermined pressure, the high frequency voltage is applied between the shower head 34 and the mounting table 35, and a plasma of raw material gas for channel is formed above the object 10 to be processed. Consequently, as shown in FIG. 1(d), for example, a channel semiconductor layer 16 composed of amorphous silicone is formed on the surface of the gate insulating film 14.

After the channel semiconductor layer 16 having a predetermined thickness is formed, the application of the voltage and the introduction of raw material gas for channel are once stopped, the plasma of raw material gas for the channel is diminished, and raw material gas for the channel inside the CVD chamber 31 is removed by evacuation.

Next, raw material gas for an ohmic layer which contains an impurity gas and a silane gas (monosilane, disilane or the like) necessary for forming an ohmic layer is introduced into the shower head 34, and ejected into the CVD chamber 31 from the ejection openings.

When the CVD chamber 31 is stabilized at the predetermined pressure, the high frequency voltage is applied between the shower head 34 and the mounting table 35, and a plasma of raw material gas for the ohmic layer is formed, so that an ohmic layer 17 composed mainly of silicon and containing an impurity is formed on a surface of the channel semiconductor layer 16 as shown in FIG. 1(e).

After the ohmic layer 17 having a predetermined thickness is formed, the application of the voltage and the introduction of raw material gas for the ohmic layer are stopped, the plasma is diminished, and the raw material gas for the ohmic layer is evacuated.

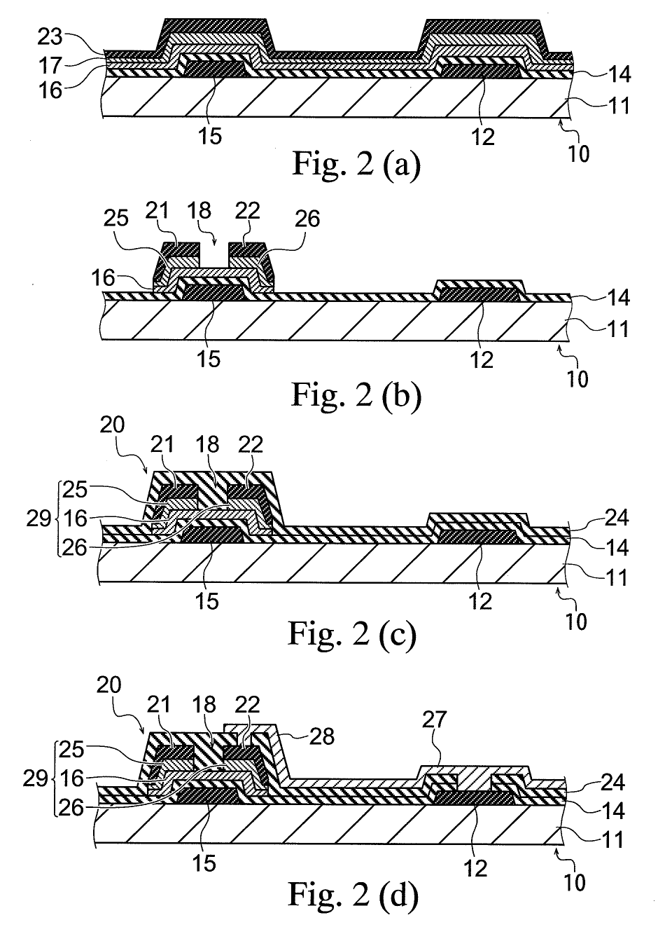

Then, the object 10 to be processed, on which the ohmic layer 17 is formed, is carried out from the plasma CVD apparatus 30 and carried into the sputtering chamber 2 as shown in FIG. 3. Thereon, a copper thin film composed mainly of copper and having a two-layer structure (second copper thin film) is formed by the same step as that of the first copper thin film 13. FIG. 2(a) illustrates a state in which the second copper thin film 23 is formed on a surface of the ohmic layer 17.

The second copper thin film 23 is constituted by a first layer containing oxygen and a second layer containing no oxygen in the same manner as in the above-described first copper thin film 13, and the first layer of the second copper thin film 23 is adhered to the ohmic layer 17.

The first layer containing oxygen has high adhesion to not only the glass substrate 11 but also to silicon. As described above, since the ohmic layer 17 is composed mainly of silicon, the second copper thin film 23 has high adhesion to the ohmic layer 17.

Next, the second copper thin film 23, the ohmic layer 17 and the channel semiconductor layer 16 are patterned by a photographing step and an etching step so that, as shown in FIG. 2(b), the channel semiconductor layer 16 is left immediately above the gate electrode 15 and, on the opposite sides thereof, those portions of the ohmic layer 17 and the second copper thin film 23 which are positioned above the channel semiconductor layer 16 and which are located immediately above the central portion of the gate electrode 15 are removed, while those portions positioned on the opposite sides of the gate electrode 15 are retained.

In FIG. 2(b), reference numerals 25, 26 denote first and second ohmic contact layers constituted by the portions of the ohmic layer 17 retained on the opposite positions of the gate electrode 15, respectively. A semiconductor layer 29 is constituted by the first and second ohmic contact layers 25, 26 and the channel semiconductor layer 16.

In FIG. 2(b), reference numerals 21, 22 denote a source electrode and a drain electrode constituted by the portions of the second copper thin film 23 retained on the opposite sides of the gate electrode 15.

The source electrode 21 is in contact with the first ohmic contact layer 25 of the semiconductor layer 29. Further, the drain electrode 22 is formed in contact with the second ohmic contact layer 26 of the semiconductor layer 29.

In this state, the source electrode 21 and the drain electrode 22 (and the other portion of the second copper thin film 23) are exposed to the surface of the object 10 to be processed. After the surfaces of the source electrode 21 and the drain electrode 22 (and the other portions of the second copper thin film 23) are exposed to the ammonia gas in the same step as in the surface treatment of the gate electrode 15 and the storage capacitor electrode 12, an interlayer insulating film 24 made of a film of silicon nitride is formed on the surfaces of the source electrode 21 and the drain electrode 22 by the same step as in the above-described formation of the gate insulating film 14, as shown in FIG. 2(c).

In FIG. 2(c), a reference numeral 20 denotes a thin film transistor (TFT) in the state that the interlayer insulating film 24 is formed.

Although the source electrode 21 and the drain electrode 22 are exposed to the silane gas at the time of forming the interlayer insulating film 24, the influence of the silane gas does not extend up to the interface between the source electrode 21 and the ohmic layer 17 or the interface between the drain electrode 22 and the ohmic layer 17 because the surface treatment is preliminarily performed with the ammonia gas. Thus, neither the source electrode 21 nor the drain electrode 22 peels from the ohmic layer 17.

In this thin film transistor 20, an opening 18 positioned immediately above the central portion of the gate electrode 15 mutually separate the first and second ohmic contact layers 25, 26 as well as the source electrode 21 and the drain electrode 22, and the opening 18 is filled with the interlayer insulating film 24.

The channel semiconductor layer 16 is the same conductivity type as the first and second ohmic contact layers 25, 26, but the impurity concentration is lowered. Thus, when a voltage is applied to the gate electrode 15, an accumulation layer having a low resistance is formed at a portion of the channel semiconductor layer 16 which is in contact with the gate electrode 15 via the gate insulating film 14, and the first and second ohmic contact layers 25, 26 are electrically connected via the accumulation layer.

Meanwhile, the channel semiconductor layer 16 may be a conductivity type opposite to that of the first and second ohmic contact layers 25, 26. In this case, when a voltage is applied to the gate electrode 15, an inversion layer of the same conductivity type as that of the first and second ohmic contact layers 25, 26 is formed at a portion of the channel semiconductor layer 16 which is in contact with the gate electrode 15 via the gate insulating film 14. Consequently, the first and second ohmic contact layers 25, 26 are electrically connected by the inversion layer.

FIG. 2(d) shows a state in which, after windows are opened at portions of the interlayer insulating film 24 above the drain electrode 22 or the source electrode 21 (here, the drain electrode 22) and above the storage capacitor electrode 12, a patterned transparent conductive film is arranged on the interlayer insulating film 24.

A reference numeral 27 of the same figure shows a pixel electrode made of that portion of the transparent conductive film which is positioned on a side of the thin film transistor 20; and a reference numeral 28 of the same figure shows a connecting portion of the transparent conductive film positioned on the thin film transistor and comprising a portion in contact with the drain electrode 22.

The pixel electrode 27 is electrically connected to the drain electrode 22 via the connecting portion 28. When the first and second ohmic contact layers 25, 26 are electrically connected, an electric current flows through the pixel electrode 27.

In FIG. 6, a reference numeral 4 shows a liquid crystal display panel in which liquid crystals 41 are arranged above the pixel electrode 27 of the object 10 to be processed, and a panel 40 having an opposite electrode 45 formed on a surface of a glass substrate 42 is opposed to the pixel electrode 27 via the liquid crystals 41.

In this liquid crystal display device 4, the light transmission rate of the liquid crystals 41 can be changed by controlling the voltage to be applied between the pixel electrode 27 and the opposite electrode 45.

In the above, a description has been provided regarding an embodiment in which the surface treatment and the formation of the films of the silicon nitride are performed for the patterned first and second copper thin films 13, 23 (gate electrode 15, the source electrode, drain electrode 21, 22). However, for some embodiments, after the surface treatment and the formation of a film of silicon nitride are performed for the first and second copper thin films 13, 23 before the patterning under the same condition as that for the patterned first and second copper thin films 13, 23, the first and second copper thin films 13, 23 may be patterned together with the film of silicon nitride, the gate electrode 15 and the storage capacitor electrode 12 may be formed from the first copper thin film 13, and the source electrode 21 and the drain electrode 22 may be formed from the second copper thin film 23.

The treatment gas to be used for the surface treatment may be constituted by the ammonia gas alone, or either one or both of a silane gas and a nitrogen gas (N₂) may be added to the treatment gas, so long as the ratio (SiₓH₂ₓ₊₂/NH₃) of the silane gas and the ammonia gas is smaller than the raw gas for the silicon nitride film.

As the silane gas, either one or both of a monosilane gas (SiH₄) and a disilane gas (Si₂H₆) may be generally used. The partial pressures of the silane gas and the ammonia gas can be adjusted by adding a carrier gas to the treatment gas and the surface treatment gas.

The surface treatment step and the silicon nitride film forming step, as well as the step of forming the other films (semiconductor layer, etc.) may be performed inside different vacuum chambers. However, if they are performed inside the same vacuum chamber (CVD chamber 31), the producing steps are simplified, and the mixing of the impurities is likely to be reduced.

The first and second copper thin films 13, 23 are not limited to the two-layer structure. A single-layer structure constituted by either one of the first layer composed mainly of copper and containing oxygen and the second layer composed mainly of copper and containing no oxygen may suffice. However, when the adhesion to the glass substrate and the silicon layer, the electric resistances, etc. is taken into consideration, the laminated structure, in which the second layer is laminated upon the first layer, is desirable.

Further, oxygen may be incorporated into the second layer. However, when the electric resistances of the electrodes are taken into consideration, the content of oxygen therein is preferably smaller than that in the first layer adhering to the glass substrate or the silicon layer.

### EXAMPLES

### Types of Treatment Gases

A target 5 composed mainly of copper and Mg as an additive was used. A first layer containing oxygen (film thickness 50 nm) and a second layer containing no oxygen (film thickness 300 nm) were laminated in the described order. Thus, a copper thin film 13 having a two-layer structure as shown in FIG. 5 was formed, thereby obtaining a test substrate.

A treatment gas was fed into the CVD chamber 31 at a flow rate of 1050 sccm, and the test substrate was exposed to the treatment gas for 30 seconds. The types of the treatment gases and a method carried out are shown as in Table 1.

Next, a film forming atmosphere at 200 Pa was formed in a time period of 15 seconds by feeding a nitrogen gas (flow rate: 5200 sccm), an ammonia gas (1050 sccm) and an SiH₄ gas (flow rate: 350 sccm) as a raw material gas into the CVD chamber 31, a plasma of the raw material gas is generated for 30 seconds by applying an electric power of 2.8 kW to the mounting table 35 in the film forming atmosphere, and a film of silicon nitride was formed in a thickness of 300 nm.

In this case, the surface treatment and the formation of the nitrided film were performed under the condition that the inner pressure (total pressure) of the CVD chamber 31 was 200 Pa and the temperature of the test substrate was 300° C.

Apart from the above, a film of silicon nitride was formed without performing the surface treatment. “Peeling tests” as described below were conducted with respect to the test substrates in which the film of silicon nitride was formed after performing the surface treatment and the test substrates in which the silicon nitride film was formed without performing the surface treatment.

[Peeling Test]

A laminated film made of the silicon nitride film and the copper thin film was cut in a grid with a knife to form small pieces of the laminated film in a matrix fashion. An adhesive tape was attached onto that surface, and peeled off. Whether the small pieces are adhered to the adhesive tape and peeled from the glass substrate or not and peeled-off positions were examined.

Evaluations were made as follows:

“o”—A case in which any of the small pieces at 25 locations was not peeled off;

“Δ”—A case in which only the silicon nitride film was peeled off, but the copper thin film remained on the surface of the glass substrate 11; and

“x”—A case in which the copper thin film was peeled off together with the silicon nitride film.

Results of the peeling tests are shown in the following Table 1 together with the types of the treatment gases that were used.

TABLE 1
Types of treatment gases and peeling test results

| | NH₃ plasma | H₂ plasma | NH₃ gas | N₂ gas |
|---|---|---|---|---|
| No treatment | treatment | treatment | treatment | treatment |
| X | X | X | ◯ | X |

In the above Table 1, “NH₃ plasma” and “H₂ plasma” are cases in which a voltage was applied to the mounting table 35 and the test substrates were exposed to the plasmatized NH₃ and H₂.

As illustrated by the results shown in the above Table 1, when the non-plasmatized ammonia gas is used as the treatment gas, the adhesions between the copper thin film and the glass substrate and that between the copper thin film and the silicon nitride film are high, so that no peeling occurs.

As a reference, a test substrate having a copper thin film 13 formed in a two-layer structure was subjected to the peeling test without being exposed to any gas, and the result of the peeling test was “o”.

### <Ratio Between SiH₄ Gas and NH₃ Gas>

After the sheet resistance of a copper thin film of a test substrate before performing the surface treatment was measured, the surface treatment was performed by feeding the SiH₄ gas together with the above-described NH₃ gas. With respect to the surface-treated copper thin film, the measurement of the sheet resistance and the above-described “Peeling test” were performed.

The flow rate of the NH₃ gas at the time of the surface treatment, the time period in which the test substrate was exposed to the treatment gas and the temperature of the test substrate conformed to the case of the above-described “Types of the treatment gases.”

The sheet resistance before the surface treatment was taken as “Before treatment,” and the sheet resistance after the exposure to SiH₄ and NH₃ was taken as “After treatment,” and they are shown in the following Table 2 together with results of the “Pealing test.”

TABLE 2
SiH₄/NH₃ and measuring results of peeling tests and sheet resistance

| Gas flow rate | | | | Sheet resistance (Ω/□) | |
|---|---|---|---|---|---|
| NH₃ | | Flow rate ratio | Peeling | Before | After |
| (sccm) | SiH₄ (sccm) | SiH₄/NH₃ | test | treatment | treatment |
| 1050 | 210 | 1/5 | X | 0.0844 | 0.1646 |
| 1050 | 70 | 1/15 | ◯ | 0.0910 | 0.0895 |
| 1050 | 35 | 1/30 | ◯ | 0.0894 | 0.0811 |

As shown in the above Table 2, when the ratio in the flow rate (flow rate ratio) between the SiH₄ gas and the NH₃ gas was ⅕, peeling occurred. In addition, the sheet resistance nearly doubled after the treatment.

To the contrary, when the ratio in the flow rate between the SiH₄ gas and the NH₃ gas is 1/15 or less, no peeling occurred. In addition, there was almost no change in the sheet resistance before and after the treatment.

Since the partial pressure of a gas inside the CVD chamber 31 is in proportion to the flow rate of the gas to be fed into the CVD chamber 31, the peeling of the electrode and the rise in the sheet resistance can be prevented if the surface is treated inside the CVD chamber 31 in an atmosphere in which the partial pressure of the SiH₄ gas is 1/15 or less of that of the NH₃.

### <Time Period of the Surface Treatment>

As a pretreatment preceding the surface treatment, a nitrogen gas atmosphere at 150 Pa was formed by introducing a nitrogen gas into the CVD chamber 31; a test substrate was placed in this nitrogen gas atmosphere; and the test substrate was heated to 320° C.

After the pretreatment, the test substrate was set to 300° C. and a surface treatment was carried out under the same condition as in the case of the above-described “Types of treatment gases,” except that the introduction time period of the treatment gas composed of NH₃ was changed to 0 second (no treatment), 5 seconds, 10 seconds, 20 seconds or 30 seconds. The introduction time period is a time elapsing from the start of introducing the treatment gas.

In this case, the pressure (total pressure) inside the CVD chamber 31 was 10 Pa as the final pressure for the introduction time period of 5 seconds, 60 Pa as the final pressure for the introduction time period of 10 seconds, and 160 Pa as the final pressure for the introduction time period of 20 seconds. When the introduction time period was 30 seconds, the pressure reached 200 Pa after 23 seconds from the start of the introduction, and was kept at 200 Pa during a period from 23 seconds to 30 seconds.

Five types of test pieces were obtained by forming silicon nitride films on test substrates after the surface treatment or before the surface treatment (no treatment) under the same film forming condition as in the case of the above-described “Types of treatment gases.” The partial pressure of the NH₃ gas was 32 Pa in the step for forming the silicon nitride film.

The above-described “peeling test” was carried out for each test piece. The results thereof are shown in Table 3.

TABLE 3
NH₃ gas treating time period and results of peeling tests

| | NH₃ gas introduction time period | | | |
|---|---|---|---|---|
| No treatment | 5 seconds | 10 seconds | 20 seconds | 30 seconds |
| X | Δ | ◯ | ◯ | ◯ |

In the case of “no treatment,” peeling occurred between the copper thin film 13 and the glass substrate 11. As to the introduction time period of 5 seconds, no peeling occurred between the copper thin film 13 and the glass substrate 11, but peeling occurred between the silicon nitride film and the copper thin film 13. When the introduction time period was 10 seconds or more, no peeling occurred between the copper thin film 13 and the glass substrate 11 and between the silicon nitride film and the copper thin film 13.

Therefore, in the above-described embodiments of the present invention, it is seen that not only the adhesion between the copper thin film 13 and the glass substrate 11 becomes higher, but also that the adhesion between the silicon nitride film and the copper thin film becomes higher.

When the introduction time period is 10 seconds or more, the inner pressure of the CVD 31 becomes 60 Pa or more. Since NH₃ gas alone is introduced into the CVD chamber 31, the total pressure inside the CVD chamber 31 is equal to the partial pressure of the NH₃ gas. Therefore, in order to prevent the peeling, it turns out that the partial pressure of the NH₃ gas within the CVD chamber 31 needs to be 60 Pa or more.

In a case of treating a large-sized substrate, peeling may occur at a central portion of the substrate if the introduction time period is short because the treatment gas does not extend over the entire surface of the large-sized substrate. Therefore, as the size of the substrate increases, the introduction time period needs to be prolonged. When the introduction time period was 30 seconds or more, no peeling occurred in the case of large-sized substrates in an envisaged size range (long side: 2400 mm). Thus, the surfaces are uniformly treated irrespective of the sizes of the substrates, so long as the introduction time period is 30 seconds or more.

### <Ratios of N₂, SiH₄ and NH₃ in the Treatment Gases>

After the sheet resistance of a copper thin film of a sample substrate was measured, the flow rate of each of the N₂, SiH₄ and NH₃ gases in the treatment gas was changed as shown in Table 4, and the surface of the sample substrate was treated through exposure to the treatment gas for 3 minutes in the state that the sample substrate was heated at 300° C.

TABLE 4
Ratios of SiH₄, N₂ and NH₃

| | | | | | | Sheet resistance (Ω/□) | |
|---|---|---|---|---|---|---|---|
| Gas flow rate (sccm) | | | Flow rate ratio | Surface | Peeling | Before | After |
| N₂ | SiH₄ | NH₃ | SiH₄/NH₃ | state | test | surface treatment | surface treatment |
| 500 | 20 | 300 | 1/15 | ◯ | ◯ | 0.0891 | 0.0838 |
| (61%) | (2.4%) | (36.6%) | | | | | |
| 500 | 40 | 300 | 2/15 | X | X | 0.0882 | 0.1297 |
| (60%) | (4.8%) | (35.7%) | | | | | |
| 500 | 0 | 300 | — | ◯ | ◯ | 0.0887 | 0.0835 |
| (63%) | (0%) | (37.5%) | | | | | |
| 500 | 20 | 0 | — | X | X | 0.0865 | 0.4320 |
| (96%) | (4.0%) | (0%) | | | | | |
| 800 | 20 | 0 | — | X | X | 0.0899 | 0.7285 |
| (97.6%) | (2.4%) | (0%) | | | | | |
| 0 | 20 | 600 | 1/30 | ◯ | ◯ | 0.0894 | 0.0811 |
| (0%) | (3.2%) | (96.8%) | | | | | |
| 0 | 20 | 300 | 1/15 | ◯ | ◯ | 0.0910 | 0.0895 |
| (0%) | (6.3%) | (93.7%) | | | | | |
| 0 | 20 | 100 | 1/5 | X | X | 0.0844 | 0.1646 |
| (0%) | (16.7%) | (83.3%) | | | | | |

* Values given by % inside parentheses in the above Table are the flow rate ratio of each gas with respect to that of the entire treatment gas.

Surfaces of the copper thin films of the sample substrates after the surface treatment were observed, and evaluations were carried out as follows:

“x”—the color of the surface of the copper thin film was changed; and

“o”—the color of the surface of the copper thin film was not changed.

The evaluation results are shown in Table 4. Further, with respect to the sample substrates after the surface treatment, the above-described “Peeling test” and measurement of the sheet resistance were performed. The results of the “Peeling test” and the sheet resistance values (before the surface treatment and after the surface treatment) are shown in Table 4.

As demonstrated by Table 4, when no NH₃ gas was added to the treatment gas, the surface state and the peeling test results were bad, and the increases in the sheet resistance values were large.

When the NH₃ gas was added to the treatment gas, the increases in the sheet resistance values were smaller as compared to the case in which no NH₃ was added. In particular, in the cases in which no silane gas was added to the treatment gas (the flow rate of the silane gas is zero) and in which the ratio in the flow rate between the SiH₄ gas and the NH₃ gas was 1/15 or less, the increases in the sheet resistance value was not only small, but the surface state and the peeling test results were also good.

As illustrated in Tables 2 and 4, in the cases where the ratio in the flow rate between the SiH₄ gas and the NH₃ gas is 1/15 or less and even if the flow rate of the SiH₄ gas and that of the NH₃ gas differed, no peeling occurred and the increases in the sheet resistance were small.

Therefore, irrespective of whether the flow rate is large or small, the peeling of the electrodes can be prevented and the resistance values can be kept low when no silane gas is added to the treatment gas or when the ratio in the flow rate between the SiH₄ gas and the NH₃ gas is 1/15 or less, that is, when the ratio in the partial pressure between the SiH₄ gas and the NH₃ gas is 1/15 or less.

What is claimed is:

1. A thin film transistor producing method for producing a thin film transistor which includes a gate electrode arranged in contact with a glass substrate, a gate insulating film arranged on a surface of the gate electrode and composed of a thin film of silicon nitride, and a semiconductor layer arranged on the gate insulating film,
the thin film transistor producing method comprising steps of:
forming a first copper thin film composed mainly of copper and constituting the gate electrode on a surface of the glass substrate by incorporating oxygen into at least a portion of the first copper thin film which adheres to the glass substrate;
introducing a treatment gas containing an ammonia gas into a vacuum chamber in which the glass substrate having a surface of the first copper thin film exposed is placed;
exposing the surface of the first copper thin film to the ammonia gas for a surface treatment without generating a plasma inside the vacuum chamber;
introducing a raw material gas, including a gas of a silicon compound containing Si and H in a chemical structure and a nitrogen containing gas including nitrogen in a chemical structure, into the vacuum chamber; and
forming a plasma of the raw material gas, thereby forming the thin film of silicon nitride on the surface of the first copper thin film.

2. The thin film transistor producing method according to claim 1, further comprising the step of exposing the surface of the first copper thin film to the ammonia gas for 10 seconds or more for the surface treatment.

3. The thin film transistor producing method according to claim 1, further comprising the step of setting the partial pressure of a monosilane gas at 1/15 or less of the partial pressure of the ammonia gas inside the vacuum chamber for the surface treatment.

4. The thin film transistor producing method according to claim 1, further comprising the step of introducing the treatment gas such that the partial pressure of the ammonia gas inside the vacuum chamber is 60 Pa or more for the surface treatment.

5. A thin film transistor producing method for producing a thin film transistor which includes a gate electrode, a gate insulating film arranged on a surface of the gate electrode, a semiconductor layer arranged on the gate insulating film, a source electrode in contact with the semiconductor layer, a drain electrode in contact with the semiconductor layer, and an insulating film in contact with the drain electrode and the source electrode and composed of a film of silicon nitride,
the thin film transistor producing method comprising the steps of:
forming a second copper thin film constituting the source electrode and the drain electrode on a surface of the semiconductor layer by incorporating oxygen into at least a portion in close contact with the semiconductor layer;
introducing a treatment gas containing an ammonia gas into a vacuum chamber in which an object to be processed is placed, the object to be processed having a surface of the second copper thin film exposed;
exposing the surface of the second copper thin film to the ammonia gas without generating a plasma inside the vacuum chamber for a surface treatment;
introducing a raw material gas including a gas of a silicon compound containing Si and H in a chemical structure and a nitrogen containing gas including nitrogen in a chemical structure into the vacuum chamber; and
forming a plasma of the raw material gas, thereby growing the thin film of silicon nitride on the surface of the second copper thin film.

6. The thin film transistor producing method according to claim 5, further comprising the step of exposing the surface of the second copper thin film to the ammonia gas for 10 seconds or more for the surface treatment.

7. The thin film transistor producing method according to claim 5, further comprising the step of setting the partial pressure of a monosilane gas at 1/15 or less of the partial pressure of the ammonia gas inside the vacuum chamber for the surface treatment.

8. The thin film transistor producing method according to claim 5, further comprising the step of introducing the treatment gas such that the partial pressure of the ammonia gas inside the vacuum chamber is 60 Pa or more for the surface treatment.

9. The thin film transistor producing method according to claim 5, wherein the semiconductor layer comprises first and second ohmic contact layers, the source electrode is in contact with the first ohmic contact layer, and the drain electrode is in contact with the second ohmic contact layer.

10. An electrode forming method for forming a copper electrode of copper or a copper alloy on a surface of glass, a surface of silicon or surface of a silicon compound exposed on an object to be processed, the method comprising the steps of:
forming a copper electrode on a substrate by incorporating oxygen into at least a layer in contact with the substrate;
performing a surface treatment by exposing a surface of the copper electrode to a treatment gas containing an ammonia gas; and
forming a thin film of silicon nitride on the copper electrode by introducing a raw material gas including a gas of a silicon compound containing Si and H in a chemical structure and a nitrogen containing gas including nitrogen in a chemical structure into a film forming atmosphere in which the surface-treated substrate is placed to generate a plasma, and forming a thin film of silicon nitride on the copper electrode.

11. The electrode forming method according to claim 10, further comprising the step of setting the partial pressure of the ammonia gas at 60 Pa or more in the treatment atmosphere, in which the substrate is placed, in the surface treatment step.

12. The electrode forming method according to claim 10, wherein a time period for exposing the copper electrode to the ammonia gas in the surface treatment step is 10 seconds or more.

13. The electrode forming method according to claim 10, wherein, in the surface treatment step, the partial pressure of the silicon compound gas contained in the treatment atmosphere is set at 1/15 or less of the partial pressure of the ammonia gas.
